(19) United States
(12) Patent Application Publication
(10) Pub. No.: US 2013/0209706 A1
(43) Pub. Date: Aug. 15, 2013

(54) APPARATUS AND METHOD FOR COATING SUBSTRATES USING THE EB/PVD PROCESS

(71) Applicants: Juergen Hotz, Muenster (DE); Pavel Seserko, Karlstein (DE); Joerg Wittich, Otzberg (DE); Gerhard Schuhmann, Krombach (DE); Johannes Schwagmann, Waechtersbach (DE); Juergen Lemke, Weinheim (DE)

(72) Inventors: Juergen Hotz, Muenster (DE); Pavel Seserko, Karlstein (DE); Joerg Wittich, Otzberg (DE); Gerhard Schuhmann, Krombach (DE); Johannes Schwagmann, Waechtersbach (DE); Juergen Lemke, Weinheim (DE)

(73) Assignee: ALD Vacuum Technologies GmbH, Hanau (DE)

(21) Appl. No.: 13/642,088

(22) PCT Filed: Apr. 20, 2011
(86) PCT No.: PCT/DE2011/000435

§ 371 Date: Jan. 2, 2013

(30) Foreign Application Priority Data
Apr. 21, 2010 (DE) 10 2010 017 896.9

(51) Int. Cl. C23C 16/48

(52) U.S. Cl. CPC C23C 16/487
USPC 427/585; 118/726; 118/727

(57) ABSTRACT

An apparatus for coating substrates with a coating material is disclosed. The apparatus includes a frame and a crucible arrangement including a first crucible and a second crucible disposed on the frame. Only one first shaft is associated with the first crucible and only one second shaft is associated with the second crucible, where the only one first and second shafts are disposed in the frame beneath the first and second crucibles, respectively. Only one first lifting device is associated with the only one first shaft and only one second lifting device is associated with the only one second shaft, where the only one first and second lifting devices are disposed in the frame. The only one first and second shafts and the only one first and second lifting devices are laterally displaceable with the frame.

This application claims the priority of International Application No. PCT/DE2011/000435, filed Apr. 20, 2011, and German Patent Document No. 10 2010 017 896.9, filed Apr. 21, 2010, the disclosures of which are expressly incorporated by reference herein.

### BACKGROUND AND SUMMARY OF THE INVENTION

The invention relates to an apparatus for coating substrates with coating material according to the EB/PVD method having a crucible arrangement comprised of at least two crucibles, wherein each crucible is disposed in an associated frame that can be displaced horizontally, and a shaft for accommodating a material bar comprised of the coating material is disposed in each frame beneath the respective crucible, and having at least one lifting device, by means of which a material bar disposed in the shaft can be inserted through the base of the crucible into the crucible, in order to be vaporized there by bombardment with an electron beam from a electron gun.

This type of arrangement is known. Two pairs of crucibles are disposed symmetrically on the head of a carousel, which forms a uniform frame for crucibles, so that by rotating the carousel 180°, the crucibles of the one pair change places crosswise with the crucibles of the other pair. A revolver having several shafts, in which material bars are stockpiled, is situated beneath every crucible. Every material bar is made up of several short solid cylindrical segments. Once a material bar has been used up except for the last segment, said segment will get stuck in the crucible so that the revolver under the crucible is able to continue to rotate unhindered until a filled revolver shaft is again located under the crucible. The lifting device pushes the new material bar against the segment remaining in the crucible, thereby releasing it from being stuck.

Because the pushed-in material must correspond to the material of the remaining segment, a revolver may only be filled with material bars made of one material. Therefore, in the case of the known apparatus, only two different materials may be used for vaporizing, which are fed respectively to the crucibles of one pair. Therefore, even though every crucible has a relatively large supply of material at its disposal, coating the substrates with more than two different materials is not possible, however. The lifting device is made of spindle drives, which are fastened on the wall of the vacuum chamber, in which the apparatus is disposed.

The object of the invention is creating a compact system, with which it is possible, where applicable, to also apply more than two layers on a substrate.

Therefore, to solve this problem, the invention provides that each crucible is assigned precisely one shaft and precisely one lifting device and that the lifting devices and the respective associated shaft are disposed on the frame associated with the crucible and are laterally displaced with said frame.

The advantage of this apparatus according to the invention is that any number of crucibles that is otherwise only limited by the size of the vacuum chamber can be made available; the shafts of said crucibles are able to be equipped with a different material. Instead of one crucible, which may be coupled to several shafts by means of a revolver, the present invention provides that every shaft is assigned its own crucible.

The crucibles may be arbitrarily offset linearly or rotationally, because the associated lifting devices are also offset respectively at the same time. In the prior art, there was a restriction in this respect, because the lifting devices were disposed on the housing of the vacuum chamber in a fixed manner, and therefore the crucibles had to occupy a defined position so that the lifting devices were able to reach the material bars of the respectively current crucible.

Basically, the frames are able to be disposed in any manner, for example, a chain-like arrangement is possible, wherein every frame has a drive in order to displace it horizontally. However, the frames are preferably partial areas of a carousel, which is rotatable around a vertical axis and is preferably provided with a central drive.

The crucibles are preferably disposed around the vertically aligned axis of the carousel so that a respective crucible is able to be rotated by a rotation of the carousel into a specific operating position that can be reached by the electron gun.

A simple design is achieved if the carousel has an upper rotary disk and a lower rotary disk, wherein the lower rotary disk is mounted vacuum-tight in the base of the vacuum chamber. In doing so, the drive shafts for the lifting device are fed through the lower rotary disk in a vacuum-tight manner so that the motors for the individual drive shafts are situated outside the vacuum chamber.

In the simplest case, the shafts are formed by cage bars arranged in a circle, which extend between the upper and lower rotary disks.

The lifting devices, which are configured as spindle drives, each have a laterally projecting extension, which engages in the associated shaft formed by cage bars.

Disposed on the upper rotary disk, which is rotatably mounted in an intermediate base of the vacuum chamber, is a crucible head supported by hollow cylinders and the crucibles are inserted in the upper side of said crucible head. The hollow cylinders each form an extension of the shafts. The crucible head is provided with cooling channels, which are attached to a cooling water connection. The cooling water supply takes place via the lower rotary disk.

A cover, which extends over the cross section of the vacuum chamber, is situated beneath the upper end of the crucible head and above the upper rotary disk and which may be cooled if need be.

Situated in the crucible head is another crucible, which does not have a material bar supply and is designated as a dummy crucible. A material to be vaporized is introduced into this crucible. This makes it possible to bring the electron beam into a neutral or intermediate position, which is required for the method described further below.

The shafts may now be filled with different materials for different substrate layers, wherein a material that is needed more frequently for coating the substrates than others may also be disposed in two or more shafts. The individual layers may now be applied in succession, in that the carousel and therefore the crucible heads are rotated so far that the crucible with the material that is currently to be vaporized is located in an operating position, where it can be reached by an electron beam, i.e., it is not situated in the shadow of the substrates and their holders.

The problem of the shadow occurs, because the electron gun is disposed above the coating zone, in which the to-be-coated substrates are situated. Because the substrates and their holders fill up the coating zone to a large extent, only a restricted space remains for guiding the electron beam.

The following problem occurs when there is a change in the crucible position: The rotation of the crucible head requires some time. In the process, the beam is not able to follow the crucible into the shadowed areas so that the beam is aimed at areas of the crucible head that lie outside of the crucible until the next crucible reaches the impact area of the beam. In order to at least minimize damage to these areas, the beam is defocused so that the beam energy that is input remains low. Despite these measures, damage cannot be ruled out altogether, however.

Therefore, according to the invention, during the rotation of the crucible head, the electron beam is directed at the dummy crucible arranged in the center of the crucible head, which dummy crucible is always in the sphere of action of the electron beam even during a rotation of the crucible head. The deflection movement is carried out very quickly and considerably more quickly than the rotational movement of the crucible head so that the electron beam is located only briefly on areas of the crucible head that are outside of the crucible and thus the energy input in the surface of the crucible head remains low enough that damage is not to be anticipated.

A further problem is that the material in the new crucible, i.e., the crucible that is situated in the operating position after a rotation of the crucible head, is still cold. In order to prevent the material from heating up rapidly, during which to-be-avoided splattering would occur, the beam energy is diminished as a rule. However, this is disadvantageous because the energy input in the coating zone is reduced overall so that the temperature therein drops and therefore also the temperature of the substrates, which in turn has a negative impact on layer quality.

Therefore, there is the problem of being able to slowly increase the energy input in the to-be-vaporized material and at the same time maintaining the temperature of the substrates.

Therefore, to solve the problem, the invention provides that the apparatus have a crucible with a dummy material and that in the event of a change to a new crucible, the electron beam is moved back and forth between the new crucible and the dummy crucible in an alternating manner, wherein the electron beam is defocused, if applicable, when it is situated on the dummy crucible.

As a result, the energy input of the beam remains constant in the coating zone so that a change in temperature is not to be anticipated. At the same time, because of the alternating change between the new crucible and the dummy crucible, the energy input in the new crucible is low to begin with so that no splattering occurs.

Control of the energy input in the new crucible may also occur in that the electron beam is first focused in the area of the new crucible and is focused more strongly with every period of alternating movement. In addition, the exposure time on the new crucible is increased with every period until it is complete, i.e., alternating movements are no longer being executed.

The invention will be explained in more detail the following on the basis of an exemplary embodiment.

### BRIEF DESCRIPTION OF THE DRAWINGS

FIG. 1 is a general view of the apparatus,

FIG. 2 is a detailed depiction of a lower rotary disk,

FIG. 3 is a view of the apparatus from below, and

FIG. 4 is a view of the apparatus from above.

### DETAILED DESCRIPTION OF THE DRAWINGS

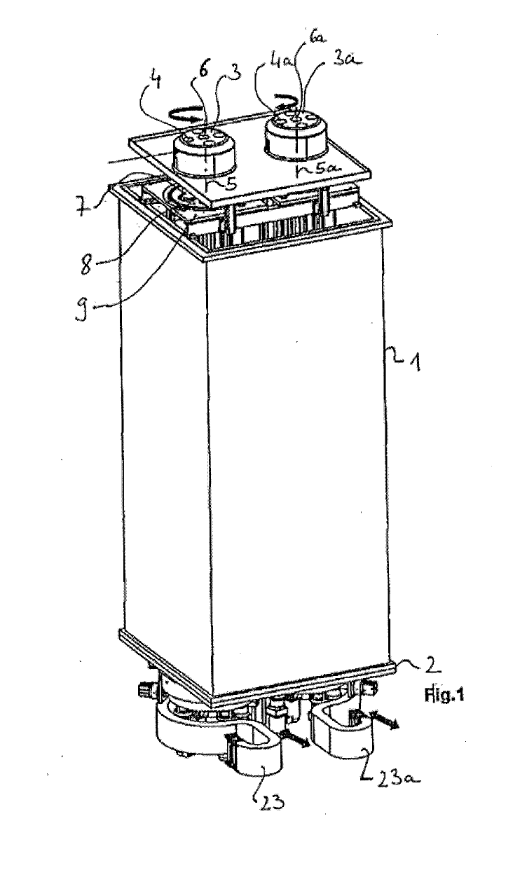

FIG. 1 shows an apparatus according to the invention, which is disposed in a vacuum chamber 1, the lower part of which is shown: The lower side of vacuum chamber 1 that is rectangular in cross section is closed by a base plate 2. A condensation hood (not shown here) is positioned in a vacuum-tight manner on the open upper end of the lower part of the vacuum chamber 1. The hood encloses a coating zone, in which the substrates are disposed on rotatable holders, which are also not shown in this case. The rotatable holders allow the substrates to rotate in a cloud of vapor so that they are coated on all sides.

A substrate receptacle is made, for example, of two elongated, horizontally running holders, on which several substrates are held next to one another. The electron beam is then only able to move in a vertical plane, which lies between the two holders. Areas to the side of this plane are in the shadow of the substrate receptacles. For this reason, the individual crucibles must be rotated into the vertical plane so that they can be reached by the electron beam.

In the present example, two apparatuses according to the invention are disposed next to each other. Therefore, there are two crucible heads 3, 3a with the same structure, which are disposed next to each other beneath the coating zone. The dual arrangement is necessary in order to create an extensive cloud of vapor in the coating zone in which a plurality of small substrates, e.g., turbine blades, is able to be coated simultaneously. Because the apparatuses are constructed identically, only one apparatus will be described in more detail in the following.

Each crucible head 3 has four crucibles 4, which are disposed in a uniformly distributed manner in a circle around a vertically running axis of rotation 5 of the apparatus. Situated in the middle of the crucible 4, preferably in the axis of rotation 5, is another crucible, specifically a dummy crucible 6, which is provided with a dummy material that is not used for coating.

The crucible head 3 is mounted on four hollow cylinders 7, which are disposed vertically positioned on an upper rotary disk 8, which is in turn rotatably mounted in an intermediate base 9 in the vacuum chamber. The hollow cylinders 7 respectively form the upper section of a shaft 10, through which to-be-vaporized material is fed from below to each crucible 4.

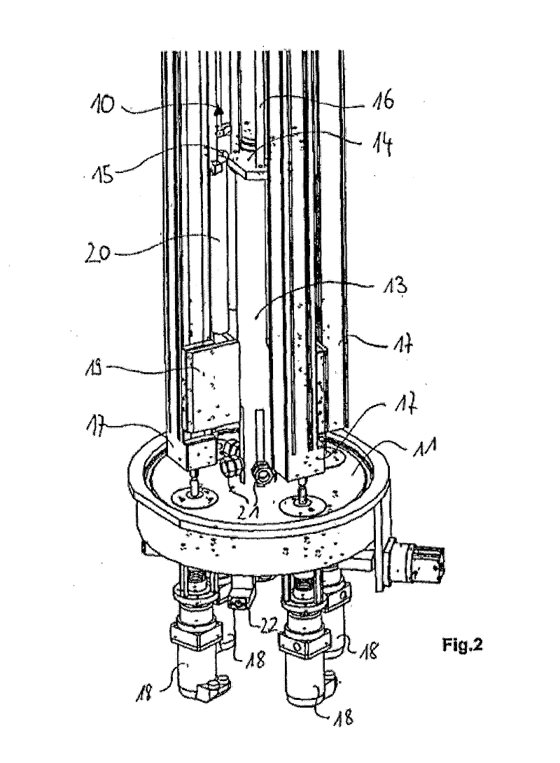

In addition, as FIG. 2 shows, a lower rotary disk 11 is disposed in the base of the vacuum chamber 1 and for this purpose, is mounted vacuum-tight in a flange 12 disposed in the base plate 2. A central column 13 runs between the upper and the lower rotary disk 8, 11. A disk 14 having four open-edge recesses 15, which align with the hollow cylinders 7 on the upper rotary disk 8, sits on a projection in the lower part of the column 13. Situated on both sides of each recess 15 are cage bars 16, which form a shaft 10 together with the central column 13. Consequently, a total of four shafts 10 are formed, each of which is limited laterally by two cage bars 16 and rearward by a third cage bar.

The material to be fed to the crucibles 4 is stacked on top of each other in the shafts 10 in the form of solid cylinders to form a material bar, which is inserted into the respective crucible 4 from below through the associated hollow cylinder 7. The lowermost solid cylinder of the material bar rests to begin with on the edge of the recess 15.

Provided between the respective radial outer edge areas of the upper and lower rotary disk 8, 11 parallel to each shaft is a respective lifting device in the form of a spindle drive 17. The spindle shaft of said spindle drive is guided outwards through the lower rotary disk 11 via a vacuum-tight rotary feed-through, where a motor 18 fastened to the underside of the rotary disk 11 is situated for every spindle drive 17.

Disposed in every spindle nut is an inwardly directed extension 19, on which an upwardly projecting pin 20 is located, which may be inserted into the associated shaft 10 through the open-edge recess 15 in the disk 14. The length of the pin 20 corresponds in this case to the length of the hollow cylinder 7 so that the pins 20 project into the crucible head when the associated extension 19 is moved completely upward. This allows even the smallest remainder of material to vaporize.

The column 13 is fed through the lower rotary disk 11 and is used both for feeding cooling water to the crucible head 3 and to carry electric energy and electric signals (not shown here) to and from sensors in the vacuum chamber 1. For this purpose, both the inner and outer sections of the column 13 have corresponding connectors, which are connected to each other inside the column. An inner water connection is identified by 21 and an outer water connection by 22. Connecting the inner water connection 21 to the cooling channels in the crucible head 3 is accomplished in this case by piping (not shown here in more detail).

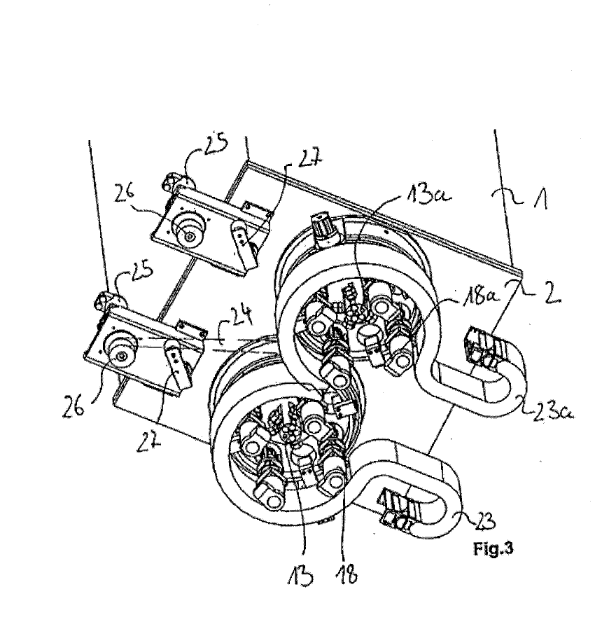

As FIG. 3 shows, the motors 18 on the two lower rotary disks 11, 11a are supplied with electricity via coilable media connections 23, 23a, which are also used for the data collection for the aforementioned sensors.

The lower rotary disk 11 is driven by a toothed belt 24, which runs via a roller 26 that is laterally disposed and driven by a motor 25 and kept under tension by a toothed belt tensioner 27. The drive for the other rotary disk 11a has an identical structure.

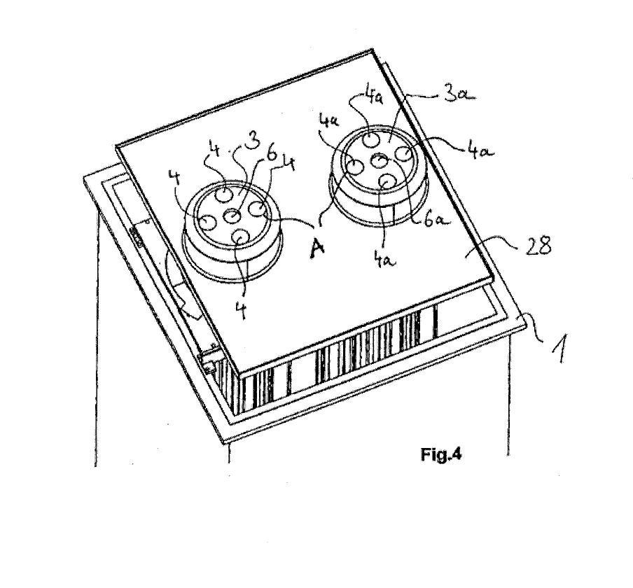

According to FIG. 4, the crucibles heads 3, 3a of the two apparatuses are situated in an expansion of a common cover 28, which prevents material from getting into the apparatuses below, which could lead to damage. The cover 28 is installed in such a way that it is possible to easily remove it for cleaning when the condensation hood is removed.

FIG. 4 shows a top view of two apparatuses according to the invention arranged next to each other. One can see two side-by-side crucible heads 3, 3a each having four crucibles 4, 4a and a fifth dummy crucible 6, 6a in the center, which is not supplied by a shaft. The operating positions A of the crucibles 4, 4a are directly opposite in a vertical plane V. The operating position is the position of the crucible at which the respective electron beam is directed in order to heat up and vaporize the material situated in the crucible.

The to-be-coated substrates are disposed to the left and right of the vertical plane V, which is defined by the two operating positions A so that the path of the electron beams is not obstructed in the vertical plane. Depending upon which material is supposed to be vaporized, one of the crucibles 4, 4a, whose shaft has been loaded with the appropriate material, is rotated into the associated operating position A. To this end, the entire apparatus is respectively rotated around the vertical axis of rotation, in that the lower rotary disks 11, 11a are driven synchronously.

During such a rotation, the electron beam is able to be guided to the center dummy crucible 6 and rests there in a neutral position as long as the crucible head 3 rotates. As soon as a new crucible 4 from the crucible circle is situated in the operating position A, the electron beam is guided back into the operating position A. The same applies to the other crucible head 3a.

The change from the neutral position to the operating position A does not have to be carried out in one step, but may be carried out by an alternating movement between the neutral position and the operating position, because an input of energy that is too strong in the still cold material in the new crucible would produce splattering.

The change is carried out so that during every period of alternating movement, the duration during which the electron beam remains on the new crucible in the operating position A is increased. In addition, the focusing of said electron beam may also be controlled. The electron beam is defocused if it is situated in the dummy crucible 6. Due to the fact that when the electron beam is defocused, its energy is introduced in a planar manner rather than in a localized manner, the material is vaporized only a little so that the dummy crucible 6 does not require any material adjustment.

Because the electron beam is not interrupted during the rotational change of the crucible 4 or when heating up the new crucible, the same amount of energy may always be introduced into crucible head 3 via the electron beam and therefore into the coating zone, thereby maintaining the temperature therein. This also relates to the substrates themselves so that the coating quality, which is also affected by the temperature, is not impacted negatively.

### LIST OF REFERENCE NUMBERS

1 Vacuum chamber

2 Base plate

3 Crucible head

4 Crucible

5 Axis of rotation

6 Dummy crucible

7 Hollow cylinder

8 Upper rotary disk

9 Intermediate base

10 Shaft

11 Lower rotary disk

12 Flange

13 Column

14 Disk

15 Recesses

16 Cage bars

17 Spindle drive

18 Motor

19 Extension

20 Pin

21 Water connection

22 Water connection

23 Media connection

24 Toothed belt

25 Motor

26 Roller

27 Toothed belt tensioner

28 Cover

1.-17. (canceled)

18. An apparatus for coating substrates with a coating material, comprising:
a frame;
a crucible arrangement including a first crucible and a second crucible, wherein the crucible arrangement is disposed on the frame;
only one first shaft associated with the first crucible and only one second shaft associated with the second crucible, wherein the only one first and second shafts are disposed in the frame beneath the first and second crucibles, respectively; and
only one first lifting device associated with the only one first shaft and only one second lifting device associated with the only one second shaft, wherein the only one first and second lifting devices are disposed in the frame;
wherein the only one first and second shafts and the only one first and second lifting devices are laterally displaceable with the frame.

19. The apparatus according to claim 18, wherein the frame is a partial area of a carousel which is rotatable around a vertical axis.

20. The apparatus according to claim 19, wherein the first and second crucibles are disposed around the vertical axis.

21. The apparatus according to claim 20 in combination with a vacuum chamber, wherein the apparatus is disposed in the vacuum chamber, and wherein the carousel has an upper rotary disk and a lower rotary disk, wherein the lower rotary disk is mounted vacuum-tight in a base of the vacuum chamber.

22. The apparatus according to claim 21, wherein a first drive shaft of the only one first lifting device and a second drive shaft of the only one second lifting device are disposed through the lower rotary disk in a vacuum-tight manner, and wherein a first motor associated with the first drive shaft and a second motor associated with the second drive shaft are disposed outside of the vacuum chamber.

23. The apparatus according to claim 19, wherein the carousel has an upper rotary disk and a lower rotary disk and wherein the only one first and second shafts are formed by respective cage bars disposed in a circle which extend between the upper and lower rotary disks.

24. The apparatus according to claim 23, wherein the only one first and second lifting devices are each spindle drives have a laterally projecting extension which are engageable in the only one first and second shafts, respectively.

25. The apparatus according to claim 21, further comprising a crucible head wherein the first and second crucibles are disposed in the crucible head, wherein the crucible head is mounted on respective upper sections of the only one first and second shafts, wherein the upper sections are disposed vertically on the upper rotary disk, and wherein the upper rotary disk is mounted in an intermediate base of the vacuum chamber.

26. The apparatus according to claim 25, wherein the crucible head includes cooling channels, wherein the cooling channels are connected to a cooling water connection, and wherein cooling water is supplyable to the cooling water connection via the lower rotary disk.

27. The apparatus according to claim 21, further comprising a crucible head wherein the first and second crucibles are disposed in the crucible head and a cover which extends over a cross-section of the vacuum chamber and is situated beneath an upper edge of the crucible head and above the upper rotary disk.

28. The apparatus according to claim 18, further comprising a crucible head, wherein the first and second crucibles are disposed in the crucible head, and further comprising a dummy crucible, wherein the dummy crucible is disposed in the crucible head.

29. The apparatus according to claim 28, wherein a material to-be-vaporized is introducible into the dummy crucible.

30. A method for operating an apparatus for coating substrates with a coating material having a crucible arrangement comprised of at least two crucibles containing coating material and a dummy crucible not containing coating material, comprising the steps of:
rotating one of the at least two crucibles containing coating material into an operating position; and
during the rotating of the one of the at least two crucibles containing coating material into the operating position, positioning an electron beam at the dummy crucible in a neutral position.

31. The method according to claim 30, further comprising the step of moving the electron beam from the neutral position to the operating position after the one of the at least two crucibles containing coating material is rotated into the operating position.

32. The method according to claim 30, further comprising the step of defocusing the electron beam when it is positioned in the neutral position at the dummy crucible.

33. The method according to claim 31, wherein the step of moving the electron beam from the neutral position to the operating position includes the step of alternating a movement of the electron beam between the neutral position and the operating position.

34. The method according to claim 33, wherein during the alternating movement, the electron beam is defocused in a first alternating movement in an area of the operating position and is increasingly focused in further alternating movements in the area of the operating position.

35. The method according to claim 33, wherein during the alternating movement, an exposure time of the electron beam is increased in an area of the operating position with every alternating movement until the alternating movement is complete.
